(19) United States
(12) Patent Application Publication
(10) Pub. No.: US 2005/0018733 A1
(43) Pub. Date: Jan. 27, 2005

(54) Semiconductor laser device and manufacturing method therefor

(75) Inventors: Kazuhiko Wada, Nara-Ken (JP); Keisuke Miyazaki, Nara-Ken (JP); Taiji Morimoto, Nara-Ken (JP); Yoshiaki Ueda, Nara-Ken (JP); Masaki Tatsumi, Nara-Ken (JP)

Correspondence Address: MORRISON & FOERSTER LLP, 1650 TYSONS BOULEVARD, SUITE 300, MCLEAN, VA, 22102, US

(73) Assignee: SHARP KABUSHIKI KAISHA, Osaka-shi (JP)

(21) Appl. No.: 10/891,507

(22) Filed: Jul. 15, 2004

(30) Foreign Application Priority Data
Jul. 22, 2003 (JP) JP2003-277292

(51) Int. Cl. H01S 5/00; H01S 3/14

(52) U.S. Cl. 372/50; 372/68

(57) ABSTRACT

An n-type AlGaAs cladding layer of a first semiconductor laser 39 to be first formed on an n-type GaAs buffer layer 22 is constructed of a two-layer structure of a second n-type AlₓGa₁₋ₓAs (x=0.500) cladding layer 23 and a first n-type AlₓGa₁₋ₓAs (x=0.425) cladding layer 24. With this arrangement, in removing by etching the second n-type cladding layer 23 located on the n-type GaAs buffer layer 22 side with HF, no cloudiness occurs since the Al crystal mixture ratio x of the second n-type cladding layer 23 is 0.500, allowing mirror surface etching to be achieved. Moreover, by virtue of selectivity to GaAs, the etching automatically stops in the n-type GaAs buffer layer 22. Even in the above case, ellipticity can be improved by matching the vertical radiation angle θ⊥ to 36 degrees since the Al crystal mixture ratio x of the first n-type cladding layer 24 located on the AlGaAs multi-quantum well active layer 25 side is 0.425.

This Nonprovisional application claims priority under 35 U.S.C. §119(a) on patent application No. P2003-277292 filed in Japan on Jul. 22, 2003, the entire contents of which are hereby incorporated by reference.

### BACKGROUND OF THE INVENTION

The present invention relates to a semiconductor laser device in which a plurality of semiconductor lasers of different wavelengths are formed on one substrate and a manufacturing method therefor.

In recent years, DVD (Digital Versatile Disc) has come to be widely used as an optical disc capable of recording/reproducing motion pictures, and users demand a drive unit also capable of utilizing recording/reproducing of information recorded in the conventional CD (Compact Disc). A red laser device having an emission wavelength in a 650-nm band is necessary for the recording/reproducing of DVD, and an infrared laser device having an emission wavelength in a 780-nm band is necessary for the recording/reproducing of CD. Conventionally, optical pickup devices have been discretely constructed of the red laser and the infrared laser, and therefore, it has been difficult to reduce the size and cost of the pickup. Accordingly, there is demanded a laser device capable of lasing in the red and infrared with one laser package.

As the laser device capable of lasing in both the red and infrared with one laser package, there are proposed a hybrid type multi-wavelength laser device in which a red laser chip and an infrared laser chip are assembled into one package and a monolithic type multi-wavelength laser device in which a laser structure for lasing in the red and a laser structure for lasing in the infrared are fabricated on one substrate. Among them, it is difficult for the hybrid type multi-wavelength laser device to improve the accuracy of two light-emitting positions since the two laser chips are assembled into one package. Therefore, the monolithic type multi-wavelength laser device of which the light-emitting position accuracy is high is widely used.

FIG. 9 shows the cross section of the monolithic type laser device. FIG. 9 shows the monolithic type laser device in which the first semiconductor laser 17 is constructed of an AlGaAs based material and the second semiconductor laser 18 is constructed of an AlGaInP based material. A manufacturing method for this laser device is disclosed in, for example, JP 2000-244060 A. A brief description is provided below.

First of all, as shown in FIG. 10A, an n-type GaAs buffer layer 2, an n-type AlGaAs cladding layer 3, an active layer (multi-quantum well structure having an emission wavelength of 780 nm) 4, a p-type AlGaAs cladding layer 5 and a p-type GaAs cap layer 6 are successively laminated on an n-type GaAs substrate 1, and a semiconductor laminate that becomes subsequently the first semiconductor laser 17 is formed. Next, a region to be left as the first semiconductor laser 17 is patterned with a resist film or the like, and thereafter, layers from the p-type GaAs cap layer 6 to the n-type AlGaAs cladding layer 3 are removed by wet etching of sulfuric-acid based non-selective etching and HF based AlGaAs selective etching or the like as shown in FIG. 10B.

Next, in order to form the second semiconductor laser 18, as shown in FIG. 11C, an n-type InGaP buffer layer 8, an n-type AlGaInP cladding layer 9, an active layer (multi-quantum well structure having an emission wavelength of 650 nm) 10, a p-type AlGaInP cladding layer 11 and a p-type GaAs cap layer 12 are successively laminated on the entire surface. Next, a region to be left as the second semiconductor laser 18 is protected with a resist film or the like, and thereafter, as shown in FIG. 11D, the unnecessary semiconductor laminate for the second semiconductor laser 18, which is laminated on the first semiconductor laser 17 and in an element isolation portion located between the first and second semiconductor laser devices 17 and 18, is removed by etching. As a result, the region of the first semiconductor laser 17 and the region of the second semiconductor laser 18 are isolated leaving the n-type GaAs substrate 1 and the n-type GaAs buffer layer 2.

Subsequently, as shown in FIG. 11E, layers from the p-type GaAs cap layer 6 partway to the p-type cladding layer 5 of the first semiconductor laser 17 are removed by etching, forming a striped ridge structure. Likewise, layers from the p-type GaAs cap layer 12 partway to the p-type cladding layer 11 of the second semiconductor laser 18 are removed by etching, forming a striped ridge structure. Subsequently, an n-type GaAs current constriction layer 13 is laminated on the entire surface. Then, as shown in FIG. 12F, the unnecessary n-type GaAs current constriction layer 13, which is located on the ridge stripes of the first and second semiconductor laser devices 17 and 18 and in the element isolation portion, is removed by etching, and thereafter, p-type AuZn/Au electrodes 14 and 15 are formed extended over the ridge stripes of the first and second semiconductor laser devices 17 and 18 and the n-type GaAs current constriction layers 13. Further, an n-side AuGe/Ni electrode 16 is formed on the back surface side of the n-type GaAs substrate 1.

The monolithic type laser device, which has the first semiconductor laser 17 constructed of the AlGaAs based material and the second semiconductor laser 18 constructed of the AlGaInP based material, is thus formed.

However, the manufacturing method of the aforementioned conventional monolithic type laser device has problems as follows. That is, in order to laminate the semiconductor laminate for the second semiconductor laser 18 after the lamination of the semiconductor laminate for the first semiconductor laser 17 on the n-type GaAs buffer layer 2, it is required to remove by etching the region unnecessary for the first semiconductor laser 17 out of the semiconductor laminate for the first semiconductor laser 17.

In the above case, when the first semiconductor laser 17 is made of an AlGaAs based material, the n-type GaAs buffer layer 2 is exposed on the surface by etching the n-type AlGaAs cladding layer 3 by the HF based AlGaAs selective etching. However, since the semiconductor laminate for the second semiconductor laser 18 is laminated on the n-type GaAs buffer layer 2, the n-type GaAs buffer layer 2 that becomes the groundwork is required to be flat, and the selective etching of the n-type AlGaAs cladding layer 3 that uses the HF based etchant is required to be mirror surface etching. This is because the semiconductor laser is normally formed by carrying out epitaxial growth on the substrate, and therefore, when the n-type GaAs buffer layer 2 that becomes the groundwork is not flat, there are the possibilities of causing a degradation in reliability and characteristic deficiency of the laser device due to defective growth.

FIG. 13 shows the etching rate dependence of AlₓGa₁₋ₓAs with respect to the Al crystal mixture ratio during etching with HF. FIG. 13 indicates that the etching rate reduces as the Al crystal mixture ratio reduces, and the etching surface becomes clouded causing surface roughness when the Al crystal mixture ratio x falls below 0.450. Therefore, in order to carry out mirror surface etching keeping selectivity to GaAs, the Al crystal mixture ratio x of AlGaAs must be at least not smaller than 0.450.

On the other hand, the semiconductor laser has a double hetero (DH) structure in which the active layer is placed between cladding layers of a low refractive index in order to carry out optical confinement in the active layer of a high refractive index. Then, in the case of the AlGaAs based material, the refractive index is changed by changing the Al crystal mixture ratio. Moreover, in order to match the radiation angle (θ⊥) in the vertical direction with the laser device, the Al crystal mixture ratio of the cladding layers 3 and 5 is adjusted. To the p-type cladding layer 5 of the ridge stripe structure as shown in FIG. 9 is generally applied an Al crystal mixture ratio x of 0.5. This is because the Al crystal mixture ratio x of the p-type cladding layer 5 becomes 0.5 for easiness of processing when a ridge stripe structure is formed by using an HF based etchant.

In order to match the radiation angle θ⊥ in the vertical direction with the laser device as described above, the Al crystal mixture ratio of the n-type cladding layer is required to be adjusted. FIG. 14 shows the θ⊥ dependence with respect to the Al crystal mixture ratio of the n-type cladding layer. For example, if it is tried to achieve θ⊥=36 degrees for the improvement of ellipticity, the Al crystal mixture ratio x becomes about 0.425. However, when the Al crystal mixture ratio x falls below 0.450, the selective etching of the mirror surface with HF becomes difficult as described above, and the formation of a monolithic type semiconductor laser becomes difficult.

### SUMMARY OF THE INVENTION

Accordingly, the object of the present invention is to provide a semiconductor laser device and manufacturing method therefor capable of easily carrying out AlGaAs selective etching of the mirror surface with an HF based etchant even when there is included a layer whose Al crystal mixture ratio x is not greater than 0.450 in the case where the unnecessary portion of the infrared laser section constructed of an AlGaAs based material is removed by etching in a monolithic type multi-wavelength semiconductor laser.

In order to achieve the above object, there is provided a semiconductor laser device having a plurality of laser structures that are constructed of semiconductor layers grown on an identical substrate and have mutually different emission wavelengths, wherein

at least one of the laser structures comprises:

a first conductive type cladding layer, an active layer and a second conductive type cladding layer, and

the first conductive type cladding layer located on the substrate side with respect to the active layer comprises two or more layers of different compositions.

According to the above-mentioned construction, the first conductive type cladding layer in at least one laser structure among the plurality of laser structures formed on the identical substrate is constructed of two or more layers of different compositions. Therefore, the first conductive type cladding layer can optimally demonstrate the characteristic with respect to the substrate and the buffer layer formed on the substrate located on one side as well as the characteristic with respect to the laser oscillation portion constructed of the active layer and the second conductive type cladding layer located on the other side.

In one embodiment of the present invention, the substrate is constructed of GaAs, and

at least one laser structure, which comprises the first conductive type cladding layer, the active layer and the second conductive type cladding layer, is constructed of an AlGaAs based material.

According to this embodiment, the substrate is constructed of GaAs, and at least one laser structure is constructed of the AlGaAs based material. Therefore, the selective etching of the AlGaAs based material using HF that has selectivity to GaAs becomes possible in removing the unnecessary region of the AlGaAs based material for the laser structure formed on the GaAs substrate.

In one embodiment of the present invention, the first conductive type cladding layer of at least one laser structure comprises two or more layers constructed of an AlGaAs based material which is expressed by AlₓGa₁₋ₓAs Al crystal mixture ratio being assumed as x (0<x<1), and

the Al crystal mixture ratio x of a layer located nearest the substrate among the two or more layers is higher than the Al crystal mixture ratio x of a layer located just above the layer.

According to this embodiment, the etching rate of the first conductive type cladding layer constructed of the AlₓGa₁₋ₓAs based material located nearest the substrate is improved. Therefore, mirror surface etching becomes possible keeping the selectivity to GaAs.

In one embodiment of the present invention, the Al crystal mixture ratio x of the layer located nearest the substrate is not smaller than 0.45.

According to this embodiment, no surface roughness occurs on the etching surface in selectively etching the AlGaAs based material using the HF, and mirror surface etching that has selectivity to the GaAs substrate or the GaAs buffer layer formed on the substrate is effected. Therefore, defective growth does not occur in growing the semiconductor material for the next laser structure, and the reliability is improved by eliminating the characteristic deficiency of the laser structure to be formed.

In one embodiment of the present invention, the layer located nearest the substrate has a layer thickness of not smaller than 0.2 μm.

According to this embodiment, the layer to be subsequently subjected to the selective etching is left in the first conductive type cladding layer even if there is variation in the etching rate of the non-selective etchant in effecting the non-selective etching on the first conductive type cladding layer, the active layer and the second conductive type cladding layer made of the AlGaAs based materials. Therefore, the etching can be achieved even if the Al crystal mixture ratio of the cladding layer for confining light is arbitrarily selected, and the degree of freedom of design is increased.

Also, there is provided a method for manufacturing the semiconductor laser device claimed in claim 3, in which an AlGaAs based material for a first laser structure is laminated on a GaAs substrate, a region unnecessary for the first laser structure in the laminated AlGaAs based material is removed, and a second laser structure having an emission wavelength different from an emission wavelength of the first laser structure is formed in the region from which the AlGaAs based material is removed, the method comprising the steps of:

forming a first conductive type GaAs buffer layer on a GaAs substrate prior to laminating the AlGaAs based material; and

removing a layer located nearest the GaAs substrate among the first conductive type cladding layers constructed of the AlₓGa₁₋ₓAs based material by etching to a boundary between the layer and the first conductive type GaAs buffer layer with HF when removing a region unnecessary for the first laser structure in the AlGaAs based material formed on the first conductive type GaAs buffer layer.

According to the above-mentioned construction, the etching is effected at a high etching rate in removing by etching the first conductive type cladding layer located nearest the substrate with HF, allowing the mirror surface etching to be achieved keeping the selectivity to GaAs. Therefore, defective growth does not occur in growing the semiconductor material for the next laser structure, and the reliability can be improved by eliminating the characteristic deficiency of the laser structure to be formed.

In one embodiment of the present invention, the first conductive type GaAs buffer layer is removed by etching after the layer located nearest the GaAs substrate among the first conductive type cladding layers is removed by etching to the boundary between the layer and the first conductive type GaAs buffer layer.

According to the above-mentioned construction, there is the possibility of the mixture of impurities such as oxygen that degrades the crystallinity in the first conductive type GaAs buffer layer that functions as an etching stop layer in removing the first conductive type cladding layer located nearest the substrate by etching. Therefore, by removing the first conductive type GaAs buffer layer before the semiconductor material for the next laser structure is grown, the crystallinity of the laser structure to be formed next is improved.

In one embodiment of the present invention, prior to the removal of the layer located nearest the GaAs substrate among the first conductive type cladding layers by etching to the boundary between the layer and the first conductive type GaAs buffer layer with the HF, etching is effected partway to the layer located nearest the GaAs substrate with an etchant that has no selectivity to the AlGaAs based material.

According to this embodiment, the layers from the second conductive type cladding layer, the active layer and partway to the layer nearest the GaAs substrate of the first conductive type cladding layer are collectively removed by non-selective etching.

As is apparent from the above, in the semiconductor laser device of this invention, the first conductive type cladding layer in at least one laser structure formed on the identical substrate is constructed of two or more layers of different compositions. Therefore, the first conductive type cladding layer can optimally demonstrate the characteristic with respect to the substrate and the buffer layer formed on the substrate located on one side as well as the characteristic with respect to the laser oscillation portion constructed of the active layer and the second conductive type cladding layer located on the other side.

In concrete, in the case where the substrate is constructed of GaAs, at least one laser structure including the first conductive type cladding layer, the active layer and the second conductive type cladding layer is constructed of the AlGaAs based material, and the Al crystal mixture ratio x of the layer located nearest the substrate among the two or more layers that constitute the first conductive type cladding layer is made to be not smaller than 0.45 and made to be higher than that of the layer located just above the layer, it becomes possible to achieve mirror surface etching with selectivity to the GaAs substrate or the GaAs buffer layer formed on the substrate by using HF in removing by etching the unnecessary region of the AlGaAs based material formed on the GaAs substrate. Therefore, the defective growth in growing the semiconductor material for the next laser structure can be prevented, and the reliability can be improved by eliminating the characteristic deficiency of the laser structure to be formed. In contrast to this, by setting the Al crystal mixture ratio x of the layer nearest the active layer among the two or more layers that constitute the first conductive type cladding layer to 0.425 (<0.45) and matching the vertical radiation angle to 36 degrees, ellipticity can be improved.

Moreover, according to the semiconductor laser device manufacturing method of this invention forms the first conductive type GaAs buffer layer on the GaAs substrate and removes by etching the layer, which is the first conductive type cladding layer constructed of the AlₓGa₁₋ₓAs based material formed on the first conductive type GaAs buffer layer and located nearest the GaAs substrate and of which the Al crystal mixture ratio x is higher than that of the layer located just above the layer, with HF to the boundary between the layer and the first conductive type GaAs buffer layer in removing the unnecessary region of the AlGaAs based material for the first laser structure laminated on this first conductive type GaAs buffer layer. Therefore, mirror surface etching can be achieved while keeping selectivity to GaAs at a high etching rate.

Therefore, the defective growth in growing the semiconductor material for the next laser structure can be prevented, and the reliability can be improved by eliminating the characteristic deficiency of the laser structure to be formed.

Furthermore, if the first conductive type GaAs buffer layer, in which impurities such as oxygen that degrades the crystallinity are possibly mixed, is removed before the semiconductor material for the next laser structure is grown, then the crystallinity of the laser structure to be formed next can be improved.

That is, according to each of the aforementioned aspects of the invention, it becomes easy to etch the AlGaAs based material by the monolithic type multi-wavelength semiconductor laser device manufacturing method, and a semiconductor laser device that has high reliability and stable characteristics can be provided. Moreover, the Al crystal mixture ratio in the AlGaAs based laser structure can be arbitrarily set, and the degree of freedom of design can be improved.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a sectional view showing the structure of the semiconductor laser device of this invention;

FIGS. 2A and 2B are sectional views of the semiconductor laser device shown in FIG. 1 in its manufacturing processes;

FIGS. 3C, 3D and 3E are sectional views in manufacturing processes subsequent to FIG. 2B;

FIGS. 4F and 4G are sectional views in manufacturing processes subsequent to FIG. 3E;

FIG. 5 is a sectional view showing the structure of the semiconductor laser device of this invention other than FIG. 1;

FIGS. 6A, 6B and 6C are sectional views of the semiconductor laser device shown in FIG. 5 in its manufacturing processes;

FIGS. 7D, 7E and 7F are sectional views in manufacturing processes subsequent to FIG. 6C;

FIGS. 8G and 8H are sectional views in manufacturing processes subsequent to FIG. 7F;

FIG. 9 is a sectional view of a conventional monolithic type semiconductor laser device;

FIGS. 10A and 10B are sectional views of the conventional semiconductor laser device shown in FIG. 9 in its manufacturing processes;

FIGS. 11C, 11D and 11E are sectional views in manufacturing processes subsequent to FIG. 10B;

FIG. 12F is a sectional view in manufacturing processes subsequent to FIG. 11E;

FIG. 13 is a graph showing the etching rate dependence of AlₓGa₁₋ₓAs with respect to the Al crystal mixture ratio during etching with HF; and

FIG. 14 is a graph showing the vertical radiation angle dependence of an n-type cladding layer with respect to the Al crystal mixture ratio.

### DETAILED DESCRIPTION OF THE PREFERRED EMBODIMENTS

This invention will be described in detail below on the basis of the embodiments thereof shown in the drawings.

### FIRST EMBODIMENT

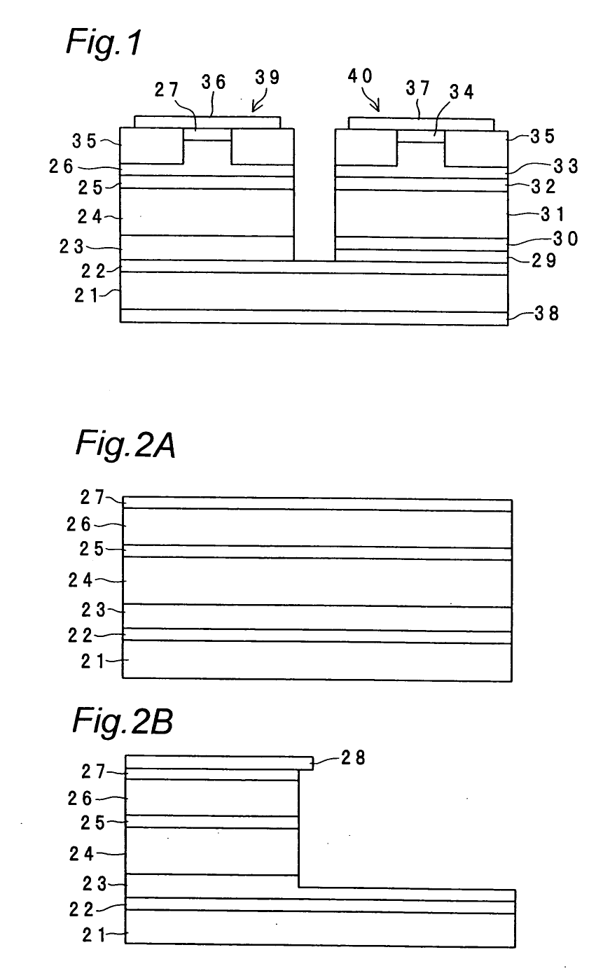

FIG. 1 shows a sectional view of the semiconductor laser device of the present embodiment. The present embodiment is related to a monolithic type two-wavelength semiconductor laser device in which the first laser structure is constructed of an AlGaAs based infrared laser, and the second laser structure is constructed of an AlGaInP based red laser. FIGS. 2A through 4G show sectional views of the present semiconductor laser device in its manufacturing processes. A manufacturing method of the monolithic type two-wavelength semiconductor laser device of the present embodiment will be described below with reference to FIGS. 2A through 4G.

First of all, as shown in FIG. 2A, an Si-doped n-type GaAs buffer layer 22 having a film thickness of 0.5 μm, a second n-type AlₓGa₁₋ₓAs (x=0.500) cladding layer 23 having a film thickness of 0.2 μm, a first n-type AlₓGa₁₋ₓAs (x=0.425) cladding layer 24 having a film thickness of 1.6 μm, a non-doped AlGaAs multi-quantum well active layer 25, a p-type AlₓGa₁₋ₓAs (x=0.500) cladding layer 26 having a film thickness of 1.2 μm and a p-type GaAs cap layer 27 having a film thickness of 0.8 μm are successively laminated on an n-type GaAs substrate 21 by the MOCVD (Metal-Organic Chemical Vapor Deposition) method.

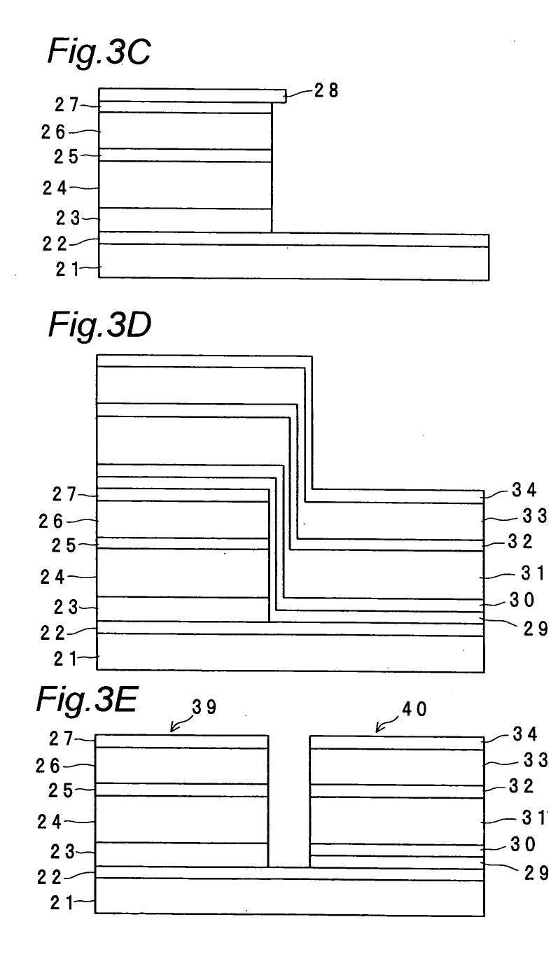

Next, a region necessary for the first laser structure is masked with a resist 28 or the like, and an unnecessary region is removed by etching. First of all, as shown in FIG. 2B, etching is effected from the p-type GaAs cap layer 27 to the neighborhood of the center of the second n-type AlₓGa₁₋ₓAs (x=0.500) cladding layer 23 by using an etchant (e.g., sulfuric acid based etchant whose sulfuric acid:peroxide:water=1:8:50) which has no selectivity to the AlGaAs based material. Subsequently, as shown in FIG. 3C, the remaining layer of the second n-type AlₓGa₁₋ₓAs (x=0.500) cladding layer 23 is removed by etching with HF.

In this case, since the Al crystal mixture ratio x of the second n-type cladding layer 23 is 0.500, no cloudiness due to HF occurs, and mirror surface etching can be achieved. Moreover, since the HF has selectivity to GaAs, the etching automatically stops at the n-type GaAs buffer layer 22.

Next, as shown in FIG. 3D, the resist 28 is removed, and an n-type GaAs buffer layer 29 having a film thickness of 0.25 μm, an n-type InGaP buffer layer 30 having a film thickness of 0.25 μm, an n-type AlGaInP cladding layer 31 having a film thickness of 1.3 μm, an active layer (multi-quantum well structure having an emission wavelength of 650 nm) 32, a p-type AlGaInP cladding layer 33 having a film thickness of 1.2 μm and a p-type GaAs cap layer 34 having a film thickness of 0.8 μm are successively laminated as the second laser structure by the MOCVD method.

Next, a region necessary for the second semiconductor laser structure is protected with a resist film or the like, and thereafter, the unnecessary second semiconductor laser structure, which is laminated on the first semiconductor laser 39 constructed of the first laser structure and in the element isolation portion located between the first and second semiconductor lasers 39 and 40, is removed by etching as shown in FIG. 3E. As a result, the region of the first semiconductor laser 39 and the region of the second semiconductor laser 40 are isolated leaving the n-type GaAs substrate 21 and the n-type GaAs buffer layer 22.

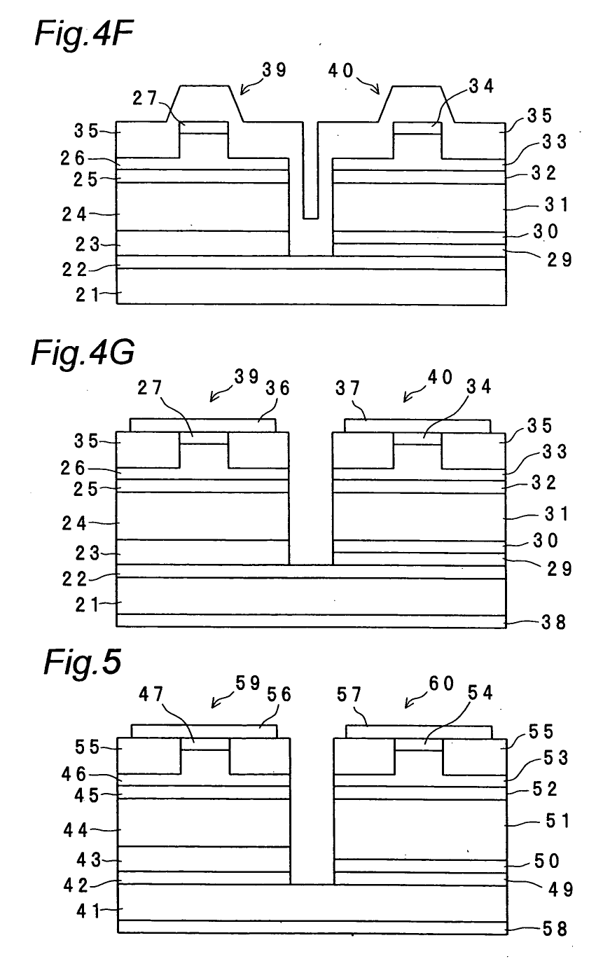

Subsequently, as shown in FIG. 4F, layers from the p-type GaAs cap layer 27 partway to the p-type cladding layer 26 of the first semiconductor laser 39 are removed by etching, forming a striped ridge structure. Likewise, layers from the p-type GaAs cap layer 34 partway to the p-type cladding layer 33 of the second semiconductor laser 40 are removed by etching, forming a striped ridge structure. Subsequently, an n-type GaAs current constriction layer 35 is laminated on the entire surface. Then, as shown in FIG. 4G, the unnecessary n-type GaAs current constriction layer 35 located on the ridge stripes of the first and second semiconductor lasers 39 and 40 and in the element isolation portion are removed by etching, and thereafter, p-side AuZn/Au electrodes 36 and 37 are formed extended over the ridge stripes of the first and second semiconductor lasers 39 and 40 and the n-type GaAs current constriction layer 35. Further, an n-side AuGe/Ni electrode 38 is formed on the back surface side of the n-type GaAs substrate 21.

As described above, in the present embodiment, the n-type AlGaAs cladding layer of the first semiconductor laser 39 first formed on the n-type GaAs buffer layer 22 is made to have a two-layer structure constructed of the second n-type AlₓGa₁₋ₓAs (x=0.500) cladding layer 23 located on the n-type GaAs buffer layer 22 side and the first n-type AlₓGa₁₋ₓAs (x=0.425) cladding layer 24 located on the AlGaAs multi-quantum well active layer 25 side.

Therefore, in removing by etching the second n-type AlₓGa₁₋ₓAs (x=0.500) cladding layer 23 located on the n-type GaAs buffer layer 22 side with HF, no cloudiness due to HF occurs since the Al crystal mixture ratio x of the second n-type cladding layer 23 is 0.500, allowing mirror surface etching to be achieved. Moreover, since the HF has selectivity to GaAs, the etching can be automatically stopped at the n-type GaAs buffer layer 22. Even in the above case, the Al crystal mixture ratio x of the first n-type AlₓGa₁₋ₓAs (x=0.425) cladding layer 24 located on the AlGaAs multi-quantum well active layer 25 side is 0.425, and therefore, ellipticity can be improved by matching the radiation angle θ⊥ in the vertical direction to 36 degrees with the laser device.

Moreover, the layer thickness of the second n-type AlₓGa₁₋ₓAs (x=0.500) cladding layer 23, which is the layer of the n-type AlGaAs cladding layer on the side nearer to the n-type GaAs substrate 21, is set to 0.2 μm. As described above, by setting the n-type cladding layer nearest the substrate 21 to 0.2 μm or greater, the second n-type AlGaAs cladding layer 23 to be subsequently subjected to AlGaAs selective etching can be left even if there is variation in the etching rate of the non-selective etchant of the sulfuric acid system or the like when the etching is effected from the p-type GaAs cap layer 27 to the neighborhood of the center of the second n-type AlGaAs cladding layer 23.

### SECOND EMBODIMENT

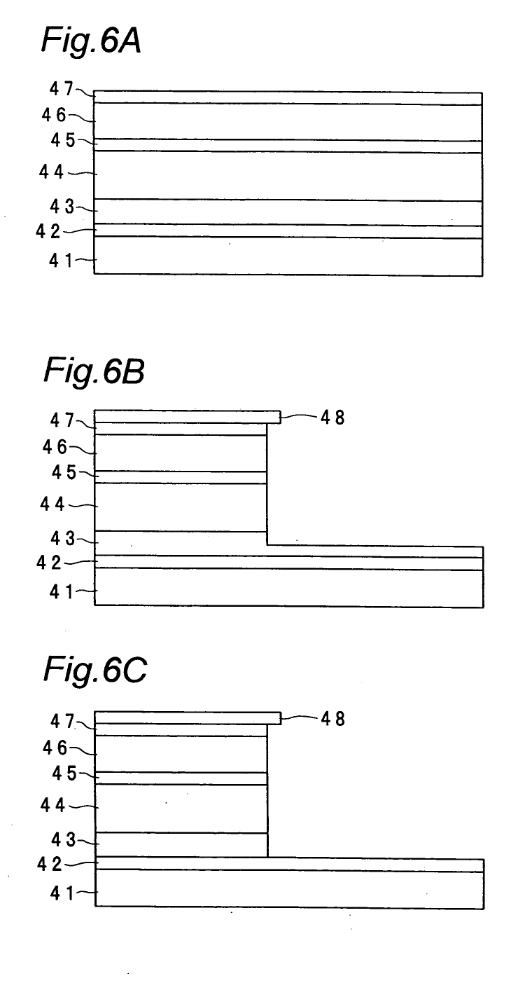

FIG. 5 shows a sectional view of the semiconductor laser device of the present embodiment. The present embodiment is related to a monolithic type two-wavelength semiconductor laser device in which the first laser structure is constructed of an AlGaAs based infrared laser and the second laser structure is constructed of an AlGaInP based red laser similarly to the case of the first embodiment. FIGS. 6A through 8H show sectional views of the present semiconductor laser device in its manufacturing processes. A manufacturing method of the monolithic type two-wavelength semiconductor laser device of the present embodiment will be described below with reference to FIGS. 6A through 8H.

First of all, as shown in FIG. 6A, an Si-doped n-type GaAs buffer layer 42 having a film thickness of 0.5 μm, a second n-type AlₓGa₁₋ₓAs (x=0.500) cladding layer 43 having a film thickness of 0.2 μm, a first n-type AlₓGa₁₋ₓAs (x=0.425) cladding layer 44 having a film thickness of 1.6 μm, a non-doped AlGaAs multi-quantum well active layer 45, a p-type AlₓGa₁₋ₓAs (x=0.500) cladding layer 46 having a film thickness of 1.2 μm and a p-type GaAs cap layer 47 having a film thickness of 0.8 μm are successively laminated on an n-type GaAs substrate 41 by the MOCVD method.

Next, a region necessary for the first laser structure is masked with a resist 48 or the like, and an unnecessary region is removed by etching. First of all, as shown in FIG. 6B, etching is effected from the p-type GaAs cap layer 47 to the neighborhood of the center of the second n-type AlₓGa₁₋ₓAs (x=0.500) cladding layer 43 by using an etchant (e.g., sulfuric acid based etchant whose sulfuric acid:peroxide:water=1:8:50) which has no selectivity to the AlGaAs based material. Subsequently, as shown in FIG. 6C, the remaining layer of the second n-type AlₓGa₁₋ₓAs (x=0.500) cladding layer 43 is removed by etching with HF.

In this case, since the Al crystal mixture ratio x of the second n-type cladding layer 43 is 0.500, no cloudiness due to HF occurs, allowing mirror surface etching to be achieved. Moreover, since the HF has selectivity to GaAs, the etching automatically stops at the n-type GaAs buffer layer 42.

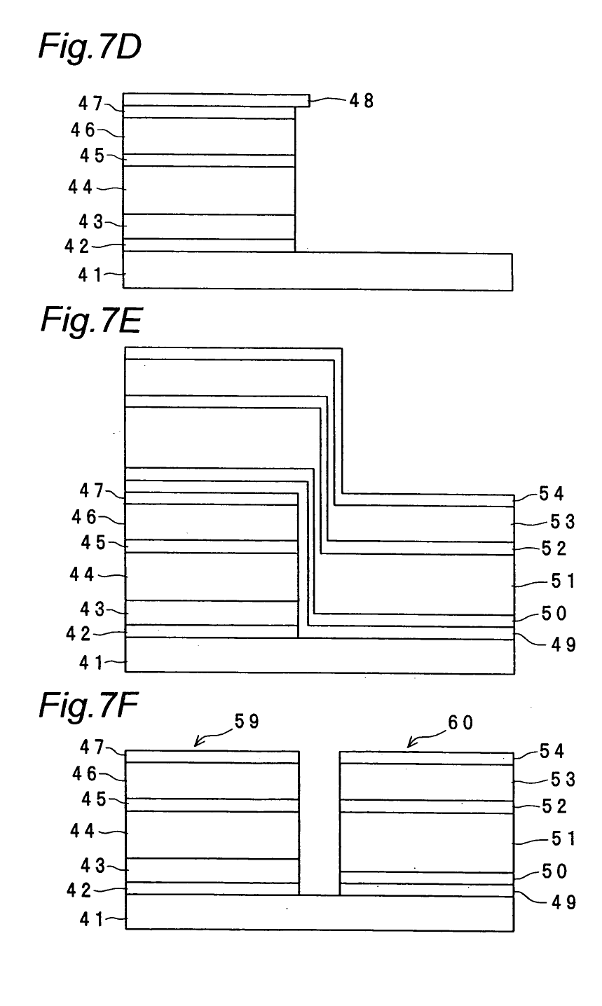

Next, as shown in FIG. 7D, the n-type GaAs buffer layer 42 is removed by etching with a sulfuric acid based etchant. There is the possibility of the mixture of impurities such as oxygen that degrades the crystallinity in the n-type GaAs buffer layer 42. Therefore, the crystallinity of the second laser structure is rather improved by removing by etching the n-type GaAs buffer layer 42 before the second laser structure is grown again.

Subsequently, as shown in FIG. 7E, the resist 48 is removed, and an n-type GaAs buffer layer 49 having a film thickness of 0.5 μm, an n-type InGaP buffer layer 50 having a film thickness of 0.5 μm, an n-type AlGaInP cladding layer 51 having a film thickness of 1.3 μm, an active layer (multi-quantum well structure having an emission wavelength of 650 nm) 52, a p-type AlGaInP cladding layer 53 having a film thickness of 1.2 μm and a p-type GaAs cap layer 54 having a film thickness of 0.8 μm are successively laminated as the second laser structure by the MOCVD method.

Next, a region necessary for the second semiconductor laser structure is protected with a resist film or the like, and thereafter, the unnecessary second semiconductor laser structure, which is laminated on the first semiconductor laser 59 constructed of the first laser structure and in the element isolation portion located between the first and second semiconductor lasers 59 and 60, is removed by etching as shown in FIG. 7F. As a result, the region of the first semiconductor laser 59 and the region of the second semiconductor laser 60 are isolated leaving the n-type GaAs substrate 41.

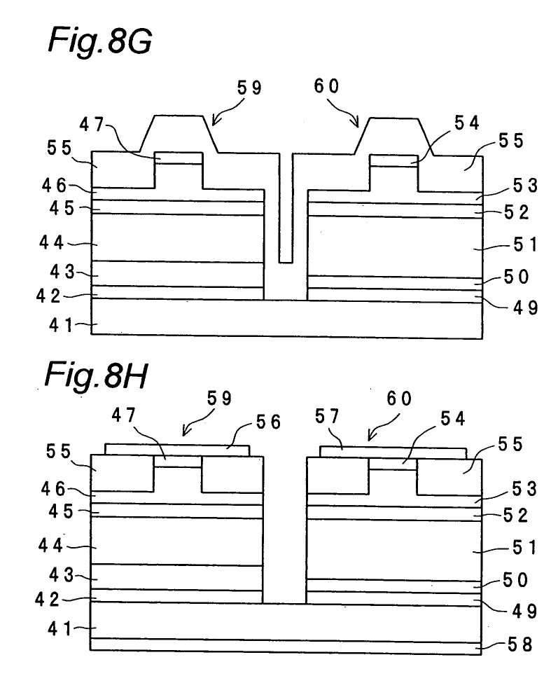

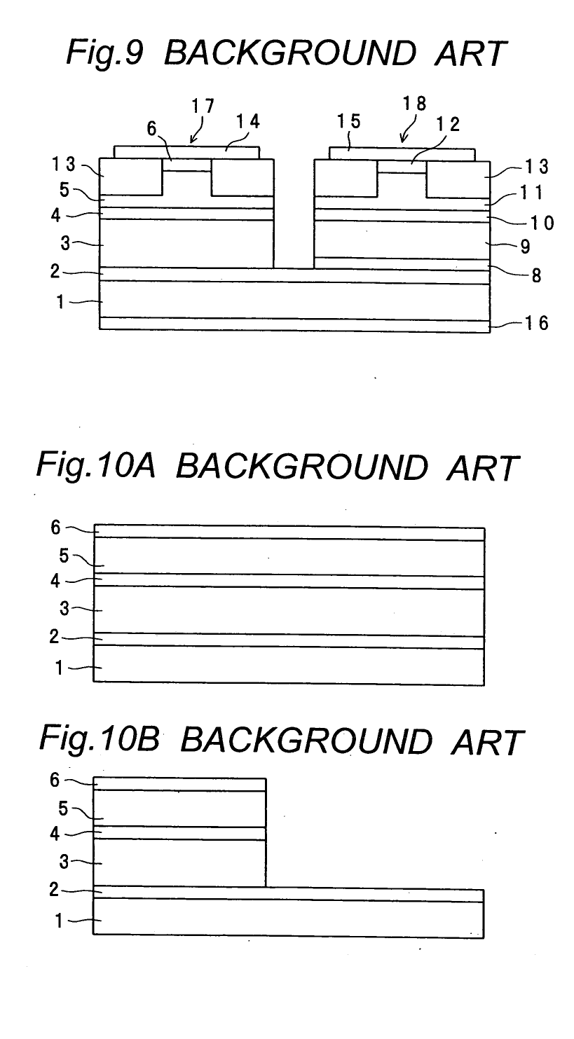

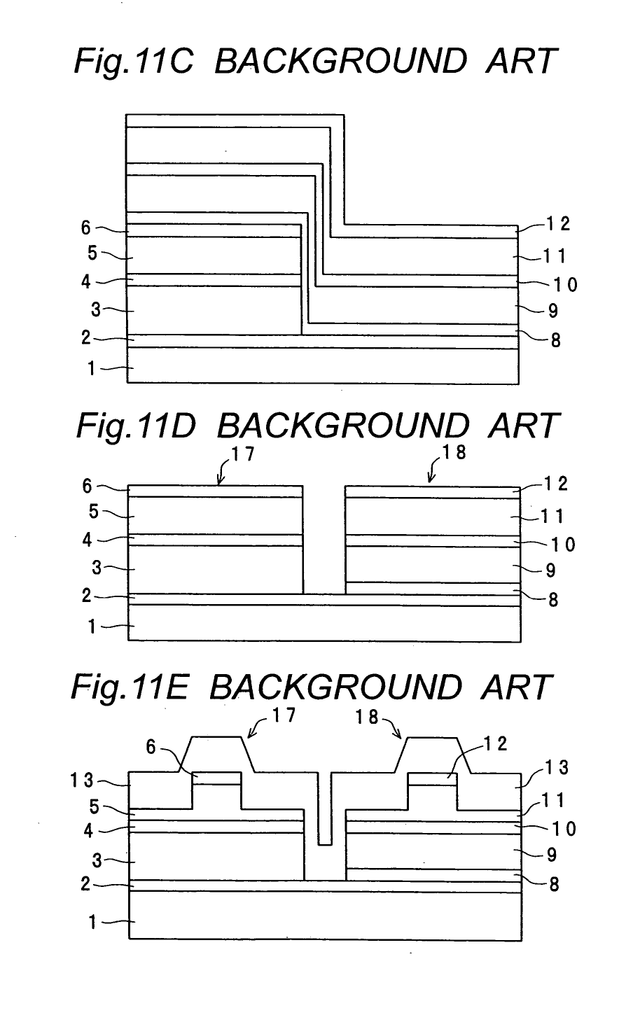

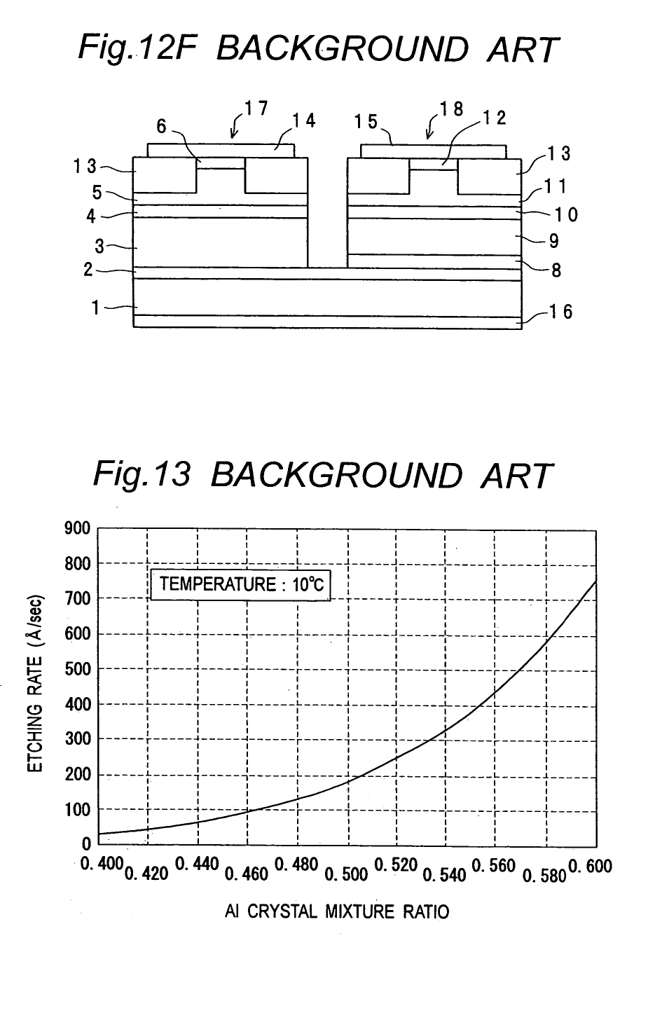

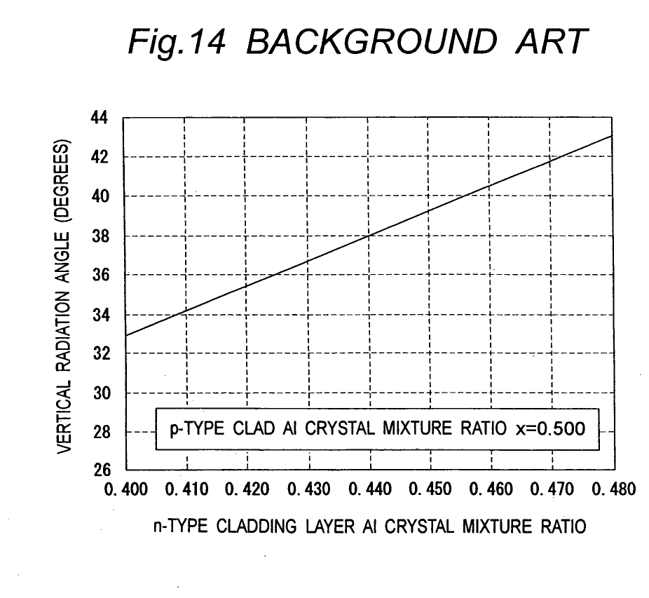

Subsequently, as shown in FIG. 8G, layers from the p-type GaAs cap layer 47 partway to the p-type cladding layer 46 of the first semiconductor laser 59 are removed by etching, forming a striped ridge structure. Likewise, layers from the p-type GaAs cap layer 54 partway to the p-type cladding layer 53 of the second semiconductor laser 60 are removed by etching, forming a striped ridge structure. Subsequently, an n-type GaAs current constriction layer 55 is laminated on the entire surface. Then, as shown in FIG. 8H, the unnecessary n-type GaAs current constriction layer 55 located on the ridge stripes of the first and second semiconductor lasers 59 and 60 and in the element isolation portion are removed by etching, and thereafter, p-side AuZn/Au electrodes 56 and 57 are formed extended over the ridge stripes of the first and second semiconductor lasers 59 and 60 and the n-type GaAs current constriction layer 55. Further, an n-side AuGe/Ni electrode 58 is formed on the back surface side of the n-type GaAs substrate 41.

As described above, in the present embodiment, in fabricating a monolithic type two-wavelength semiconductor laser device in which the first laser structure is constructed of an AlGaAs based infrared laser and the second laser structure is constructed of an AlGaInP based red laser in the first embodiment, the unnecessary region is removed by etching by masking the region necessary for the first laser structure with the resist 48, and thereafter, the n-type GaAs buffer layer 42 as an etching stop layer is removed by etching.

Therefore, by removing the n-type GaAs buffer layer 42 in which the impurities such as oxygen that degrades the crystallinity is possibly mixed before the second laser structure is grown again, the crystallinity of the second semiconductor laser 60 can be improved in addition to the effect of the first embodiment.

That is, according to each of the aforementioned embodiments, it becomes easy to etch the AlGaAs based material for the first semiconductor lasers 39 and 59 with regard to the monolithic type multi-wavelength laser device, and a semiconductor laser device that has high reliability and stable characteristics can be provided.

Although each of the aforementioned embodiments has been described on the basis of the example in which two semiconductor lasers are formed on an identical semiconductor substrate, it is needless to say that this invention can be applied to the case where three or more semiconductor lasers are formed on an identical semiconductor substrate.

Moreover, this invention is limited to none of the aforementioned embodiments, and it is also acceptable to variously combine the growth methods, the crystal compositions and the conductive types with one another.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A semiconductor laser device having a plurality of laser structures that are constructed of semiconductor layers grown on an identical substrate and have mutually different emission wavelengths, wherein
at least one of the laser structures comprises:
a first conductive type cladding layer, an active layer and a second conductive type cladding layer, and
the first conductive type cladding layer located on the substrate side with respect to the active layer comprises two or more layers of different compositions.

2. The semiconductor laser device as claimed in claim 1, wherein
the substrate is constructed of GaAs, and
at least one laser structure, which comprises the first conductive type cladding layer, the active layer and the second conductive type cladding layer, is constructed of an AlGaAs based material.

3. The semiconductor laser device as claimed in claim 2, wherein
the first conductive type cladding layer of at least one laser structure comprises two or more layers constructed of an AlGaAs based material which is expressed by AlₓGa₁₋ₓAs Al crystal mixture ratio being assumed as x (0<x<1), and
the Al crystal mixture ratio x of a layer located nearest the substrate among the two or more layers is higher than the Al crystal mixture ratio x of a layer located just above the layer.

4. The semiconductor laser device as claimed in claim 3, wherein
the Al crystal mixture ratio x of the layer located nearest the substrate is not smaller than 0.45.

5. The semiconductor laser device as claimed in claim 4, wherein
the layer located nearest the substrate has a layer thickness of not smaller than 0.2 μm.

6. A method for manufacturing the semiconductor laser device claimed in claim 3, in which an AlGaAs based material for a first laser structure is laminated on a GaAs substrate, a region unnecessary for the first laser structure in the laminated AlGaAs based material is removed, and a second laser structure having an emission wavelength different from an emission wavelength of the first laser structure is formed in the region from which the AlGaAs based material is removed, the method comprising the steps of:
forming a first conductive type GaAs buffer layer on a GaAs substrate prior to laminating the AlGaAs based material; and
removing a layer located nearest the GaAs substrate among the first conductive type cladding layers constructed of the AlₓGa₁₋ₓAs based material by etching to a boundary between the layer and the first conductive type GaAs buffer layer with HF when removing a region unnecessary for the first laser structure in the AlGaAs based material formed on the first conductive type GaAs buffer layer.

7. The semiconductor laser device manufacturing method as claimed in claim 6, wherein
the first conductive type GaAs buffer layer is removed by etching after the layer located nearest the GaAs substrate among the first conductive type cladding layers is removed by etching to the boundary between the layer and the first conductive type GaAs buffer layer.

8. The semiconductor laser device manufacturing method as claimed in claim 6, wherein,
prior to the removal of the layer located nearest the GaAs substrate among the first conductive type cladding layers by etching to the boundary between the layer and the first conductive type GaAs buffer layer with the HF, etching is effected partway to the layer located nearest the GaAs substrate with an etchant that has no selectivity to the AlGaAs based material.

9. The semiconductor laser device manufacturing method as claimed in claim 7, wherein,
prior to the removal of the layer located nearest the GaAs substrate among the first conductive type cladding layers by etching to the boundary between the layer and the first conductive type GaAs buffer layer with the HF, etching is effected partway to the layer located nearest the GaAs substrate with an etchant that has no selectivity to the AlGaAs based material.
